(19) United States
(12) Patent Application Publication
(10) Pub. No.: US 2009/0151767 A1
(43) Pub. Date: Jun. 18, 2009

(54) COMPOSITE THERMOELECTRIC MATERIAL AND METHODS FOR MAKING

(75) Inventors: Fred Sharifi, Niskayuna, NY (US); Julin Wan, Rexford, NY (US); Kristen Hall Brosnan, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/958,516

(22) Filed: Dec. 18, 2007

(51) Int. Cl. H01L 35/02

(52) U.S. Cl. 136/207; 136/236.1

(57) ABSTRACT

Thermoelectric materials, devices, and systems are presented. One embodiment is a composite material comprising a matrix comprising a thermoelectric material; and an electrically conducting phase disposed within the matrix. The electrically conducting phase has a lower electrical resistivity than the thermoelectric material, and it forms a continuous electrically conducting path through the matrix from a first surface of the material to a second surface of the material. Another embodiment is a device, comprising a thermoelectric element. This element is made of the above composite material. A further embodiment is a thermoelectric system, made of a heat source, a heat sink, and the thermoelectric device disposed in thermal communication with the heat source and heat sink. The system may be configured for power generation or for thermal management.

### BACKGROUND

This invention relates to thermoelectric materials. More particularly, this invention relates to composite thermoelectric materials, and devices made from such materials for heat transfer and power generation applications. This invention also relates to methods for making composite thermoelectric materials and devices.

Heat transfer devices may be used for a variety of heating/cooling and power generation/heat recovery systems, such as refrigeration, air conditioning, electronics cooling, industrial temperature control, waste heat recovery, and power generation. These devices are desirably scalable to meet the thermal management needs of a particular system and environment. However, existing heat transfer devices, such as those relying on refrigeration cycles, often use environmentally unfriendly refrigerants, have limited lifetime, and are bulky due to their reliance on mechanical components such as compressors.

In contrast, solid-state devices offer certain advantages, such as high reliability, reduced size and weight, reduced noise, lower maintenance, and lower potential for adverse environmental impact. For example, thermoelectric devices transfer heat by flow of electrons and holes through pairs of p-type and n-type semiconductor thermoelements, which form structures that are connected electrically in series and thermally in parallel. However, due to the relatively high cost and low efficiency of existing thermoelectric devices, they are currently restricted to small-scale applications, such as automotive seat coolers, generators in satellites and space probes, and for local heat management in electronic devices.

At a given operating temperature, the efficiency of thermoelectric devices can be characterized by the figure-of-merit that depends on the Seebeck coefficient, electrical conductivity, and thermal conductivity of the thermoelectric materials employed for such devices. Many techniques have been used to increase the efficiency of thermoelectric devices through improving the figure-of-merit value. For example, in some devices two-dimensional superlattice thermoelectric materials have been employed for increasing the figure-of-merit value of such devices. Such devices may require deposition of two-dimensional superlattice thermoelectric materials through techniques such as molecular beam epitaxy or vapor phase deposition. However, such techniques are time- and resource-intensive—and thus are relatively expensive; are limited to small-scale applications; and require significant expertise.

Accordingly, there is a need to provide thermoelectric materials with a higher figure of merit than conventional materials. There is a further need for thermoelectric devices with improved efficiency than can be attained with conventional thermoelectric elements. Moreover, there is a need for methods to fabricate such materials and devices.

### BRIEF DESCRIPTION

Embodiments of the present invention are provided to meet these and other needs. One embodiment is a composite material comprising a matrix comprising a thermoelectric material; and an electrically conducting phase disposed within the matrix. The electrically conducting phase has a lower electrical resistivity than the thermoelectric material, and it forms a continuous electrically conducting path through the matrix from a first surface of the material to a second surface of the material.

Another embodiment is a device, comprising a thermoelectric element. This element is made of the above composite material. A further embodiment is a thermoelectric system, made of a heat source, a heat sink, and the thermoelectric device disposed in thermal communication with the heat source and heat sink. The system may be configured for power generation or for thermal management.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic of one exemplary embodiment of a thermoelectric composite as described herein;

FIG. 2 is a schematic of one exemplary process for making a thermoelectric composite;

FIG. 3 is a magnetoresistance plot for a thermoelectric composite in accordance with one embodiment of the present invention;

FIG. 4 is a schematic cross section of a thermoelectric device in accordance with one embodiment of the present invention;

FIG. 5 is a schematic cross section of a system for thermal management in accordance with one embodiment of the present invention; and

FIG. 6 is a schematic cross section of a system for power generation in accordance with one embodiment of the present invention.

### DETAILED DESCRIPTION

Embodiments of the present invention are in part based on the surprising discovery of materials having a particular composition and microstructure that show an enhancement in thermoelectric performance over conventional thermoelectric materials.

The basic principle behind the operation of any thermoelectric device is the Seebeck effect of the thermoelectric material used in the device. The Seebeck effect states that if a temperature difference exists across the ends of a material, a voltage difference will arise between the ends due to the temperature difference. The Seebeck coefficient (which is a property of the thermoelectric material, also called the “thermopower”) is the resulting voltage per degree of temperature difference.

The efficiency of a thermoelectric material is known to depend on material properties through a figure-of-merit (ZT), where

$$ZT = {S}^{2} T \frac{σ}{λ} \qquad ( 1 )$$

Here, S is the Seebeck coefficient, σ is the electrical conductivity of the thermoelectric material, λ is the thermal conductivity of the thermoelectric material, and T is the temperature at which the Seebeck coefficient, electrical conductivity, and thermal conductivity are measured. A material having a high Seebeck coefficient, a high electrical conductivity, and low thermal conductivity will have a high figure-of-merit. Typically, figure-of-merit is measured as an average figure-of-merit (ZTavg), where Tavg is the temperature difference between the hot and cold side. Throughout this description, a material is considered a “thermoelectric material” if it has a maximum ZT greater than about 0.1.

In one embodiment, a material is a composite comprising a matrix and an electrically conducting phase disposed within the matrix. As used herein, the term “matrix” means a material that makes up over 50 volume percent of the microstructure. In some embodiments, the matrix makes up at least 70 volume percent of the microstructure, and in particular embodiments, the matrix makes up at least 90 volume percent of the composite microstructure. The matrix is made up, at least in part, and in some embodiments substantially entirely, of a thermoelectric material. Many thermoelectric materials are semiconductors that can be doped to be either p-type or n-type; it will be appreciated that doped compositions of both p-type and n-type materials are included without limitation in embodiments described herein. Examples of suitable matrix materials include antimonides, arsenides, tellurides, and germanides. Lead telluride is a particular example of a suitable thermoelectric material used in some embodiments of the present invention.

The “electrically conductive” term is used herein to denote a material used in fabrication, or a phase in the microstructure, of the composite material that has a lower electrical resistivity than the thermoelectric material. Moreover, the electrically conducting phase forms a continuous electrically conducting path through the matrix from a first surface to a second surface. Without being bound by theory, it is believed that the remarkable thermoelectric properties observed for this composite material is attributable to this microstructure, which provides an inhomogeneous distribution of current flow through the material.

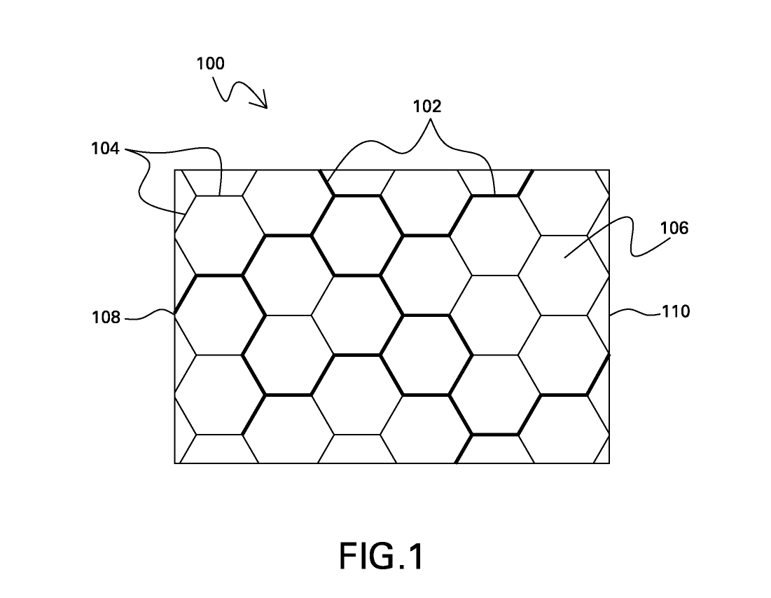

In some embodiments, as shown in FIG. 1, the electrically conducting phase 102 is disposed at grain boundaries 104 of the matrix 106. Electrically conducting phase 102 thus, in these embodiments, forms a continuous path for charge flow across the composite 100 via the grain boundaries 104 of the at least partially (and in some cases substantially fully) crystalline matrix 106. Grain boundaries 104 may provide a convenient location within composite 100 in which to precipitate or otherwise dispose electrically conducting phase 102 within composite 100, because grain boundaries 102 typically present an internal surface upon which disposition of secondary phases is thermodynamically favored, and because grain boundaries 102 often form a continuous network throughout the microstructure of a material, thus forming a pathway from a first surface 108 to a second surface 110. While in general some or all of the conductive phase may be present in locations other than the grain boundaries, in some embodiments at least about 90 percent by volume of the electrically conducting phase 102 present in the composite 100 is disposed at the grain boundaries 104 of the matrix material 106.

Examples of materials suitable for use as the electrically conductive phase include any material having an electrical conductivity higher than the thermoelectric material of the matrix. Metallic materials, including those that include lead, bismuth, copper, silver, or gadolinium, typically have suitably high electrical conductivity for use in embodiments described herein, for instance. A metallic material may be, without limitation, an alloy or compound of at least one metal element, or it may be a single metal element acting alone (with allowance for incidental impurities). In a particular embodiment, the electrically conducting phase comprises at least 80 percent by volume elemental lead, including, in certain cases, about 100% elemental lead.

In one particular embodiment, the thermoelectric material of the matrix includes, at least in part, lead telluride, while the electrically conducting phase includes, at least in part, elemental lead. As explained in more detail, below, this embodiment lends itself well to scaleable manufacturing methods.

Various methods may be used to fabricate the composite material described above. In one embodiment, a thermoelectric material and an electrically conducting material, as those terms are defined above, are mixed together using any convenient mixing technique and then consolidated to produce the material described above. In certain embodiments, mixing is done in the liquid phase, and so the consolidation step would involve solidification from the melt, rather than a solid-state compaction. In some embodiments, the mixture of thermoelectric material with electrically conducting material is achieved at least in part by coating the electrically conducting material onto particles that include the thermoelectric material, such as by atomic layer deposition, chemical vapor deposition, physical vapor deposition, or any convenient coating process. The coating thus deposited may be up to about 1 micrometer, in some exemplary embodiments, and up to about 100 nanometers in other embodiments. Of course, conventional mechanical mixing techniques such as ball milling may be a viable alternative in some embodiments.

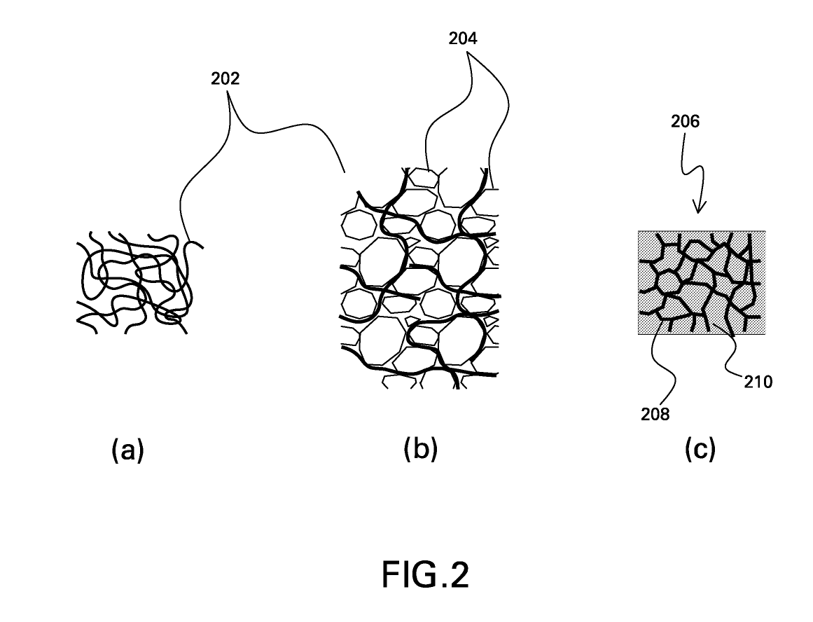

In particular embodiments, the thermoelectric material is mixed with a nano-structured material that at least partially includes the electrically conducting material. A nano-structured material, as that term is used herein, means a structure that has at least one dimension with a length of up to about 100 nanometers. Examples of nano-structured materials include nano-structured flakes and nano-structured wires. For example, as shown in FIG. 2, copper nanowires 202 are provided in (a), such as by hydrazine reduction of a copper salt or other suitable technique; and then in (b) are mixed with particles 204 of lead telluride by ball milling and ultrasonication, for instance. The mixture is consolidated to form an embodiment of the composite 206 as described above, with a continuous network of conductive copper 208 running through a lead telluride matrix 210.

Consolidation of the mixture, in some embodiments, is achieved at least in part by a sintering process, such as, for example, spark plasma sintering. Spark plasma sintering, due to its relative speed advantages over conventional sintering techniques, is especially useful where nano-structured materials are to be consolidated and the avoidance of coarsening of the nano-structures is desirable.

The amount of electrically conductive material provided to form the composite may vary in accordance with the particular materials and processes selected for particular embodiments. In some embodiments, the amount may be relatively small, such as up to about 20% by volume, or even up to about 5% by volume in certain embodiments, provided that sufficient electrically conductive material is present in the resultant composite to form the continuous electrically conducting path through the matrix, as described previously.

In some embodiments, the mixture described above is processed so as to accumulate the electrically conductive material in the required connected path through the matrix, such as at grain boundaries of the matrix, for instance. This processing may be done, for instance, by first dissolving the electrically conducting material in the matrix (either in the solid or the liquid phase), solidifying the mixture (if needed) and precipitating the electrically conducting material at the thermodynamically favored grain boundary locations. Alternatively, the electrically conductive material may in some cases have a lower melting point than the matrix, and so heating the composite to a temperature intermediate to the respective melting points and then cooling may allow the electrically conductive material to melt, coalesce at grain boundaries or other convenient location, and solidify to form the requisite continuous conductive path.

In an alternative embodiment, a thermoelectric material is synthesized by reaction between a first moiety and a second moiety. For example, in lead telluride, the first moiety may be lead and the second may be tellurium. The first moiety is provided in excess of the amount needed to form the stoichiometric composition of the thermoelectric material. At the completion of the synthesis reaction, the excess first moiety may reside at the grain boundary regions of the thermoelectric material to form a substantially continuous network. In particular embodiments, the reaction described above occurs in the liquid phase, that is, where all reactants and products are molten.

In another alternative embodiment, a thermoelectric material is provided. The thermoelectric material is a compound of a first moiety and a second moiety. For example, in lead telluride, the first moiety may be lead and the second may be tellurium. Electrically conductive material, such as, for example, material of the first moiety, is provided to form a mixture with the thermoelectric material. In some embodiments, the mixture is heated to a temperature sufficient to melt the thermoelectric material and the first moiety. In some embodiments, this melt is solidified to form a substantially crystalline matrix phase comprising the thermoelectric material, with the conductive phase disposed along grain boundaries of the crystalline matrix phase. Cooling the melt sufficiently slowly to form a crystalline ingot directly upon solidification may result in the desired structure. Alternatively, the structure may be formed by quenching the melt to form a supersaturated solid solution of the conductive phase in the matrix phase, and then precipitating the conductive phase along grain boundaries of the crystalline matrix phase. In some cases this quenching step may be done quite rapidly, using known rapid solidification techniques such as spin casting or splat quenching.

In further alternative embodiments, a displacement reaction is used to form the composite in situ. First, a thermoelectric material as described above is provided. The thermoelectric is a compound of a first moiety and a second moiety. For example, in lead telluride, the first moiety may be lead and the second may be tellurium. A reactant material is then provided. The reactant material is reacted with the thermoelectric material, resulting in a displacement reaction in which the first moiety is displaced from the thermoelectric compound in favor of the reactant. The first moiety is rejected from the thermoelectric and thereby forms a conductive phase having a lower electrical resistivity than the thermoelectric material, and this phase is then disposed by subsequent processing to form the continuous path through the thermoelectric-containing matrix, as described previously.

In some embodiments, the displacement reaction is achieved at least in part by mixing the thermoelectric material with the reactant material to form a mixture, and heating the mixture to a temperature sufficient to melt the thermoelectric material, thereby forming a melt in which the reaction takes place. In some embodiments, this melt is solidified to form a substantially crystalline matrix phase comprising the thermoelectric material, with the conductive phase disposed along grain boundaries of the crystalline matrix phase. Alternatives for solidification of the melt in this embodiment are similar to those previously described.

The reactant material is selected to have a higher affinity for the second moiety of the thermoelectric material than the first moiety has. In some embodiments, the reactant material includes without limitation gadolinium, barium, silver, lanthanum, or copper. Examples of suitable thermoelectric materials have been previously described above. In a particular embodiment, lead telluride is reacted with a reactant such as silver to form silver telluride and elemental lead. The reacted mixture is processed as described above to form a composite having a crystalline matrix, made of lead telluride with a small amount of silver telluride, and a continuous network of lead so disposed at the grain boundaries of the matrix to form an electrically conductive path through the matrix.

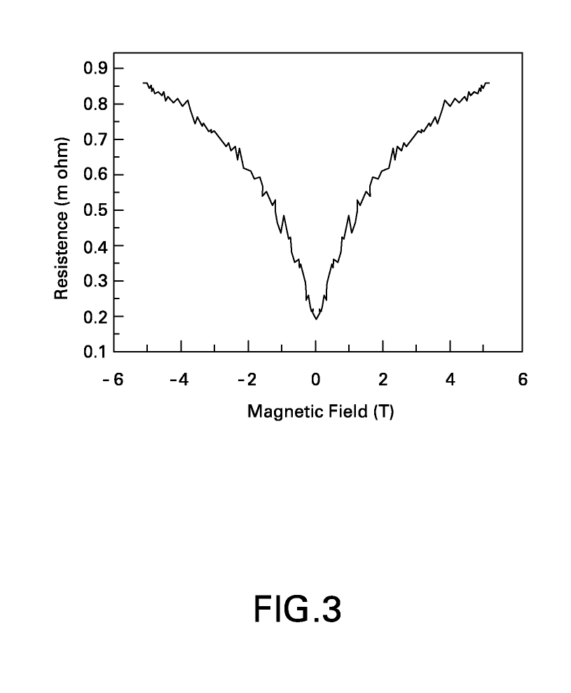

The composite material described herein has shown remarkable properties. For example, FIG. 3 is a graph of electrical resistance as a function of magnetic field strength (“magnetoresistance”) for a lead telluride-matrix composite. In typical materials, magnetoresistance is quadratic with applied magnetic field. However, as shown in FIG. 3, the thermoelectric composite composition demonstrated here shows electrical resistance proportional to the magnetic field strength raised to a power of less than 2. Accompanying this remarkable behavior, the material also demonstrates an enhancement in either (1) thermopower relative to the thermoelectric material of the matrix phase, whereby the Seebeck coefficient of the composite at a given carrier concentration is greater than the Seebeck coefficient of the thermoelectric matrix phase alone; or in (2) the carrier concentration, whereby the composite carrier concentration of the composite at a given Seebeck coefficient is greater than the carrier concentration of the thermoelectric matrix phase.

Embodiments of the present invention also include devices made using the composite thermoelectric composition described above, and systems for heating, cooling, or power generation, that include one or more of such devices. In general, thermoelectric devices include a thermoelectric element made of a thermoelectric material. In embodiments of the present invention, the thermoelectric material at least partially includes the material described herein.

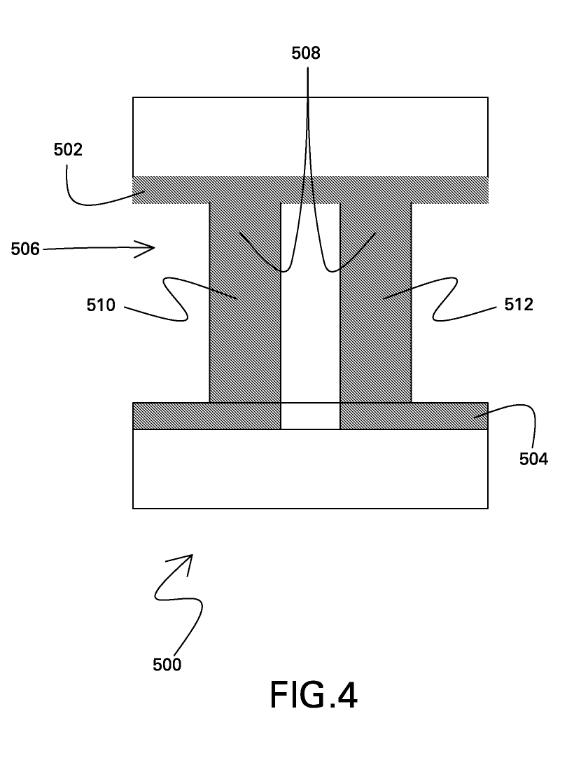

As illustrated in FIG. 4, a thermoelectric device 500 in accordance with embodiments of the present invention includes, among other items, a first electrode 502 spaced apart from a second electrode 504, with a thermoelectric element 506 extending between the two electrodes 502, 504. Element 506 includes one or more legs 508 made of a thermoelectric material. In the embodiment shown, element 506 includes two legs 508: an n-type leg 510 and a p-type leg 512, which legs are, due in part to the illustrated patterning of the electrodes 502, 504, configured thermally in parallel and electrically in series, in accordance with device design principles widely used in the art. Legs 508 comprise the thermoelectric material previously described herein. It should be noted that one or more elements 506 having the p-type and n-type legs 510 and 512 may be employed based upon a desired power generation or heat transfer capacity of the system 500; the illustrated embodiment depicts only one pair of such elements but should not be construed as limiting the number of elements to any particular number.

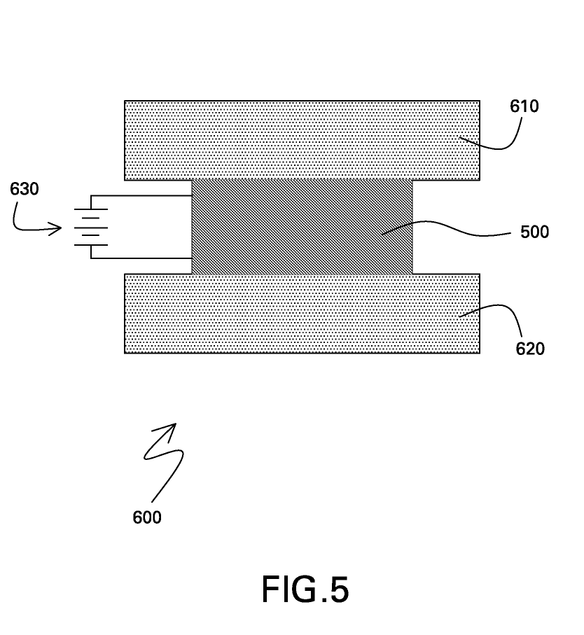

Device 500 may be used for heating or cooling applications by maintaining an electrical potential to drive electrical current through the thermoelectric element 506. Thus, as illustrated in FIG. 5, a system for thermal management (that is, either heating or cooling an article as desired) includes at least a heat source 610, a heat sink 620, and the thermoelectric device 500 as described above disposed in thermal communication with heat source 610 and heat sink 620. A potential source 630 (such as, for example, a battery or power supply) provides the electrical potential to drive current through device 500.

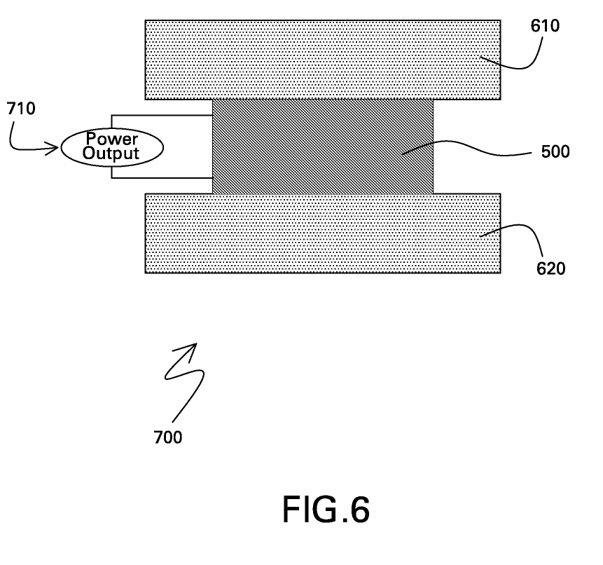

Alternatively, device 500 may be used in power generation applications by maintaining a thermal gradient across element 506. Thus, as illustrated in FIG. 6, a system 700 for power generation includes a heat source 610, a heat sink 620, and the thermoelectric device 500 as described in previous embodiments, with device 500 disposed in thermal communication with both source 610 and sink 620. An output device 710 is disposed in electrical communication with device 500 to store, use, measure, or otherwise apply the electrical potential generated by device 500 as a result of the thermal gradient between source 610 and sink 620. Examples of output devices include without limitation sensors, actuators, meters, batteries, capacitors, lights, electrical equipment, and any other device that is capable of accepting an electrical voltage input.

In the systems 600, 700 described herein, source 610 and sink 620 can be any of a variety of objects. Of course, heat sink 620 can be any object that releases heat from device 500. Heat source 610 can be any object that transfers heat to device 500. In heating applications, for example, the item to be heated serves as the heat sink 620, while in cooling applications, the item to be cooled serves as the heat source 610.

The various aspects of the techniques described above may find utility in a variety of heating/cooling systems, such as refrigeration, air conditioning, electronics cooling, industrial temperature control, and so forth. The thermoelectric devices as described above may be employed in air conditioners, water coolers, climate controlled seats, and refrigeration systems including both household and industrial refrigeration. For example, such devices may be employed for cryogenic refrigeration, such as for liquefied natural gas (LNG) or superconducting devices. Further, the devices as described above may be employed for cooling of components in various systems, such as, but not limited to vehicles, internal combustion engines, turbines, and aircraft engines. For example, a thermal transfer device may be coupled to a component of an aircraft engine such as a fan, compressor, combustor, or a turbine case. An electric current may be passed through the thermal transfer device to create a temperature differential to provide cooling of such components.

Alternatively, the device described herein may utilize a naturally occurring or manufactured heat source to generate power. For example, the devices described herein may be used in conjunction with geothermal based heat sources where the temperature differential between the heat source and the ambient (whether it be water, air, etc.) facilitates power generation. Similarly, in an aircraft engine the temperature difference between the engine core air flow stream and the outside air flow stream results in a temperature differential through the engine casing that may be used to generate power. Such power may be used to operate or supplement operation of sensors, actuators, or any other power applications for an aircraft engine or aircraft. Additional examples of applications within which thermoelectric devices described herein may be used include gas turbines, steam turbines, diesel and other internal combustion engines, vehicles, and so forth. Such thermoelectric devices may be coupled to photovoltaic or solid oxide fuel cells that generate heat thereby boosting overall system efficiencies.

The devices described above may also be employed for thermal energy conversion and for thermal management. It should be noted that the materials and the manufacturing techniques for the device may be selected based upon a desired thermal management need of an object. Such devices may be used for cooling of microelectronic systems such as microprocessor and integrated circuits. Further, the thermal transfer devices may be employed for thermal management of semiconductor devices, photonic devices, and infrared sensors.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A material comprising:
a matrix comprising a thermoelectric material; and
an electrically conducting phase disposed within the matrix, the electrically conducting phase having a lower electrical resistivity than the thermoelectric material, wherein the electrically conducting phase forms a continuous electrically conducting path through the matrix from a first surface of the material to a second surface of the material.

2. The material of claim 1, wherein the electrically conducting phase is disposed at grain boundaries of the matrix.

3. The material of claim 2, wherein at least 90% by volume of the electrically conducting phase present in the material is disposed at the grain boundaries of the matrix.

4. The material of claim 1, wherein the thermoelectric material comprises a material selected from the group consisting of antimonides, arsenides, tellurides, and germanides.

5. The material of claim 1, wherein the thermoelectric material comprises a telluride.

6. The material of claim 1, wherein the thermoelectric material comprises lead telluride.

7. The material of claim 1, wherein the electrically conducting phase comprises a metallic conductor.

8. The material of claim 1, wherein the electrically conducting phase comprises at least one metal selected from the group consisting of lead, bismuth, copper, silver, and gadolinium.

9. The material of claim 1, wherein the electrically conducting phase comprises at least 80% by volume elemental lead.

10. The material of claim 1, wherein the matrix comprises lead telluride and the electrically conducting phase comprises elemental lead.

11. A device, comprising:
a thermoelectric element comprising a thermoelectric material, the material comprising
a matrix comprising a thermoelectric material; and
an electrically conducting phase disposed within the matrix, the electrically conducting phase having a lower electrical resistivity than the thermoelectric material, wherein the electrically conducting phase forms a continuous electrically conducting path through the matrix from a first surface of the material to a second surface of the material.

12. The device of claim 11, wherein the thermoelectric element is configured to generate electricity in response to a thermal gradient input.

13. The device of claim 11, wherein the thermoelectric element is configured to control temperature in response to an electric potential input.

14. A vehicle comprising the device of claim 11.

15. A power generation system comprising the device of claim 11.

16. The power generation system of claim 15, wherein the device is disposed within the system to generate electricity from waste heat generated by the system.

17. A thermoelectric system, comprising:
a heat source;
a heat sink; and
a thermoelectric device disposed in thermal communication with the heat source and the heat sink, wherein the thermoelectric device comprises a thermoelectric element comprising
a matrix comprising a thermoelectric material; and
an electrically conducting phase disposed within the matrix, the electrically conducting phase having a lower electrical resistivity than the thermoelectric material, wherein the electrically conducting phase forms a continuous electrically conducting path through the matrix from a first surface of the material to a second surface of the material.

18. The system of claim 17, further comprising a potential source disposed to drive electric current through the thermoelectric element.

19. The system of claim 17, further comprising an electrical output device disposed in electrical communication with the thermoelectric element.

20. The system of claim 17, wherein the heat source or the heat sink is selected from a group consisting of a vehicle, an internal combustion engine, a turbine, and an aircraft engine.

21. The system of claim 17, wherein the heat source or the heat sink is selected from a group consisting of a cooling system, a heating system, a solid oxide fuel cell, and a geothermal source.

22. A thermoelectric composition comprising:
a thermoelectric matrix phase and an electrically conducting phase disposed within the matrix, the electrically conducting phase having a lower electrical resistivity than the thermoelectric material;
wherein the thermoelectric composition has the following properties:
a. a magnetoresistance property whereby the electrical resistance of the material is proportional to the magnetic field strength raised to an exponential power, the exponential power being less than 2; and
b. an enhancement that is one of the following: (1) a thermopower enhancement, wherein the Seebeck coefficient of the composition at a given carrier concentration is greater than the Seebeck coefficient of the thermoelectric matrix phase, or (2) a carrier concentration enhancement, where the carrier concentration of the composition at a given Seebeck coefficient greater than the carrier concentration of the thermoelectric matrix phase.
